(19) United States
(12) Patent Application Publication
(10) Pub. No.: US 2024/0137150 A1
(43) Pub. Date: Apr. 25, 2024

(54) METHODS AND SYSTEMS FOR EARLY TERMINATION OF ITERATIVE DETECTION AND DECODING

(71) Applicant: Samsung Electronics Co., Ltd., Suwon-si (KR)

(72) Inventors: Mojtaba Rahmati, San Diego, CA (US); Hyukjoon Kwon, San Diego, CA (US); Dongwoon Bai, San Diego, CA (US)

(21) Appl. No.: 18/074,372

(22) Filed: Dec. 2, 2022

Related U.S. Application Data
(60) Provisional application No. 63/418,346, filed on Oct. 21, 2022.

(51) Int. Cl. H04L 1/00; H04W 52/02

(52) U.S. Cl. CPC H04L 1/005; H04L 1/0061; H04W 52/0209

(57) ABSTRACT

A system and a method are disclosed for determining early termination during an iterative detection and decoding (IDD) procedure. The method may include computing, during the IDD procedure, one or more log-likelihood ratios (LLRs) of one or more cyclic-redundancy checks (CRC), and determining that at least one of the LLRs predict a failure of a CRC check and, in response, terminating the IDD procedure.

This application claims the priority benefit under 35 U.S.C. § 119(e) of U.S. Provisional Application No. 63/418,346, filed on Oct. 21, 2022, the disclosure of which is incorporated by reference in its entirety as if fully set forth herein.

### TECHNICAL FIELD

The disclosure generally relates to reducing power consumption in communications systems. More particularly, the subject matter disclosed herein relates to methods and systems for early termination of iterative detection and decoding.

### SUMMARY

In digital communication systems, such as those utilized in long term evolution (LTE) and/or 5th generation new radio (5G NR) technologies, multiple-input and multiple-output (MIMO) systems transmit encoded modulated symbols from one device to another, for example, from a one user equipment (UE) to another UE. In 5G NR, the information exchange may be between an LDPC decoder and the symbol detector, and in LTE, the information exchange may be between a Turbo decoder and the symbol detector. Accordingly, the UE demodulates and decodes the received symbols in order to utilize the information that was received.

There is an ongoing effort to improve the quality of the received symbols while reducing power consumption. Accordingly, the methods and systems described throughout the present disclosure are directed to terminating iterative detection and decoding (IDD) when it is determined that performing further iterations of IDD may not likely improve the decoded symbols.

According to some embodiments of the present disclosure, a method may include computing, during an iterative detection and decoding (IDD) procedure, one or more log-likelihood ratios (LLRs) of one or more cyclic-redundancy checks (CRC), and determining that at least one of the LLRs predict a failure of a CRC check and, in response, terminating the IDD procedure.

The one or more LLRs may be computed for each code block of a transmit block in response to the transmit block failing a CRC check after a global iteration of the IDD procedure.

The terminating the IDD procedure may be performed for all code blocks of the transmit block, the code blocks including at least one code block where the LLR predicts a passing CRC check.

The terminating the IDD procedure may be performed for one or more code blocks where the LLRs predicted a failure of the CRC check, and wherein the IDD procedure continues for at least one code block where the LLR predicts a passing CRC check.

The one or more LLRs may be computed for a transmit block in response to the transmit block failing a CRC check after a global iteration of the IDD procedure.

The LLR prediction of failure of the CRC check may be based on computing mutual information between transmitted bits and the LLR at an output of a decoder, and wherein the mutual information is less than a threshold value.

The LLR prediction of failure of the CRC check may be based on computing an average value of magnitudes of all of the LLRs, and wherein the average value of the magnitudes is less than a threshold value.

The LLR prediction of failure of the CRC check may be based on computing a sign change ratio (SCR) between the LLR of an input of a decoder and the LLR of an output of the decoder, and wherein the SCR is less than a threshold value.

The LLR prediction of failure of the CRC check may be based on computing a number of zero LLRs at an input of a decoder and at an output of a decoder, and wherein a number of zero LLRs is less than a threshold value.

The IDD may be performed for reducing power consumption in a new radio (NR) or a long-term evolution (LTE) communications system.

According to some embodiments of the present disclosure, a receiver is disclosed. The receiver may include a processing circuit including a detector and a decoder coupled with the detector, wherein the processing circuit is configured to compute, during an iterative detection and decoding (IDD) procedure, one or more log-likelihood ratios (LLRs) of one or more cyclic-redundancy checks (CRC); and

determine that at least one of the LLRs predict a failure of a CRC check and, in response, terminating the IDD procedure.

The one or more LLRs may be computed for each code block of a transmit block in response to the transmit block failing a CRC check after a global iteration of the IDD procedure.

The terminating the IDD procedure may be performed for all code blocks of the transmit block, the code blocks including at least one code block where the LLR predicts a passing CRC check.

The terminating the IDD procedure may be performed for one or more code blocks where the LLRs predicted a failure of the CRC check, and wherein the IDD procedure continues for at least one code block where the LLR predicts a passing CRC check.

The one or more LLRs may be computed for a transmit block in response to the transmit block failing a CRC check after a global iteration of the IDD procedure.

The LLR prediction of failure of the CRC check may be based on computing mutual information between transmitted bits and the LLR at an output of a decoder, and wherein the mutual information is less than a threshold value.

The LLR prediction of failure of the CRC check may be based on computing an average value of magnitudes of all of the LLRs, and wherein the average value of the magnitudes is less than a threshold value.

The LLR prediction of failure of the CRC check may be based on computing a sign change ratio (SCR) between the LLR of an input of a decoder and the LLR of an output of the decoder, and wherein the SCR is less than a threshold value.

The LLR prediction of failure of the CRC check may be based on computing a number of zero LLRs at an input of a decoder and at an output of a decoder, and wherein a number of zero LLRs is less than a threshold value.

The IDD may be performed for reducing power consumption in a new radio (NR) or a long-term evolution (LTE) communications system.

According to some embodiments of the disclosure, a method may include performing at least two global iterations (GI) of an iterative detection and decoding (IDD) procedure, computing, during the IDD procedure, log-likelihood ratios (LLRs) for each code block of a transmit block in response to the transmit block failing a CRC check after a first GI of the IDD procedure and determining that a processing budget for a second GI of the IDD is greater than a remaining code block processing budget, in response to determining that at least one of the LLRs predict a failure of a CRC check and, in response terminating the IDD procedure.

### BRIEF DESCRIPTION OF THE DRAWING

In the following sections, the aspects of the subject matter disclosed herein will be described with reference to exemplary embodiments illustrated in the figures, in which:

FIG. 1 is a block diagram of a symbol detector and a decoder of an electronic device, according to an embodiment of the present disclosure.

FIG. 2 is a flow chart of a method for determining early termination of an IDD procedure, according to an embodiment of the present disclosure.

FIG. 3 is a flow chart of a method for determining early termination of an IDD procedure, according to another embodiment of the present disclosure.

FIG. 4 is a flow chart of a method for determining early termination of IDD, according to various embodiments of the present disclosure

FIG. 5 is a flow chart of a method for determining early termination of IDD when two or more global iterations of IDD are performed, according to various embodiments of the present disclosure.

FIG. 6 is a block diagram of an electronic device in a network environment, according to an embodiment.

FIG. 7 is a system block diagram of a first electronic device in communication with a second electronic device, according to various embodiments of the present disclosure.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

The terms “success,” “successful,” “pass,” “passes,” “passing,” and “not failing” as used herein are all intended to be synonymous. The terms “fail,” “failing,” “not successful,” and “does not pass” as used herein are all intended to be synonymous.

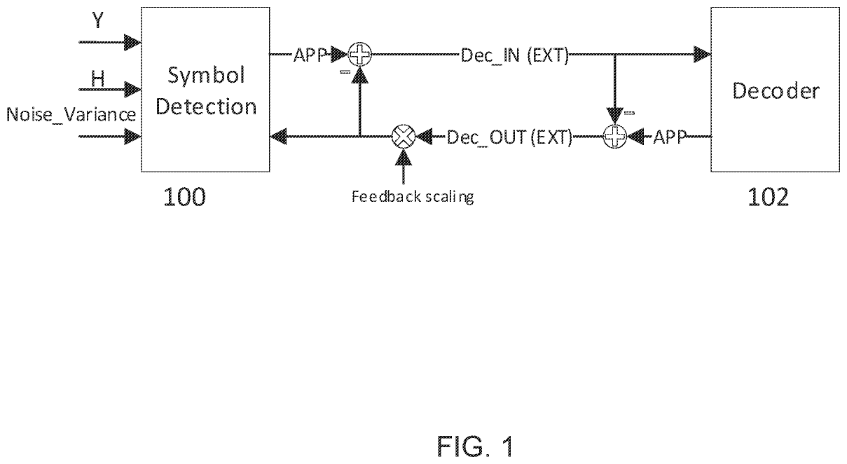

FIG. 1 is a block diagram illustrating information flow of a device implementing an IDD message exchange structure. In some embodiments, a signal is transmitted from a transmitting device, such as a transmitting UE where the signal is encoded into symbols and modulated. The device illustrated in FIG. 1 may be, for example, a receiving UE where detection and decoding is performed on a received signal. As illustrated, a received signal (Y), a channel estimation (H), and noise variance are provided as inputs to a symbol detector 100, and an output (APP LLR) of the symbol detector 100 is provided as an input (Dec_IN) to decoder 102. Here, the symbol detector 100 may be configured to demodulate the received signal (Y) and generate a log-likelihood ratio (LLR) of the detected symbols at the output (APP LLR) to assign a confidence score to each bit that is detected. The confidence score may be the confidence that the bit is going to be a 1 or a 0. LLRs may be APP or extrinsic (EXT) depending on the application. For example, the output of the decoder 102 may be APP LLR, but DEC_OUT as shown in FIG. 1 is EXT LLR, which may be represented as LXT LRR=APP LLR−DEC_IN. Accordingly, the LLRs may then be provided to the decoder 102 where the LLRs are decoded to generate ones and zeros, and a CRC check is applied to determine whether the decoded bits are successful or not. Accordingly, in some instances, the decoding process may fail. That is, the decoding process may not generate the correct results because the decoder, if successful, should generate the same symbol that was encoded by the transmitter side when the symbol was encoded and modulated and should also pass the CRC check. Thus, if the decoding is unsuccessful, the decoding process may be performed again and again by utilizing or exploiting available information such as the LLR. Accordingly, a feedback path may be created from the decoder to the detector to improve the results in the next iteration of detecting and decoding. These further iterations may generate improved results because the first iteration did not have this decoder feedback but the future iterations do.

Accordingly, the output from the decoder 102 may be provided back to the detector 100 as feedback, and this feedback may be utilized to improve the detection by the detector 100 according to a technique referred to as iterative detection and decoding (IDD). IDD is a technique that can improve performance gain in any coded modulation schemes such as those mentioned above. This may be particularly useful in cellular communication systems such as 4G LTE and 5G NR. However, the iterative operation of IDD is power consuming and while performing many iterations may improve quality of decoded symbols, performing excessive iterations can negatively impact battery life and/or memory usage. Thus, techniques for performing IDD with early termination to stop or reduce the iteration process to reduce power consumption, while still achieving improved results is desired. Herein the present disclosure, one iteration of detecting and decoding is referred to as a global iteration (GI).

To reduce the impact on battery life, memory, and/or time, resulting from performing IDD, IDD may be terminated. However, it may be undesirable to blindly terminate IDD without giving appropriate consideration to the value added as a consequence of the multiple iterations being performed by the IDD. In other words, if performing another iteration of IDD is likely going to improve the next results, then this benefit may outweigh the cost of power consumption, time, and/or memory usage. On the other hand, if performing another iteration of IDD is not likely going to improve the next results, then it may be more beneficial to terminate the IDD and not consume further power, time, and/or memory.

According to various embodiments of the present disclosure, techniques to predict success or failure after IDD will be disclosed. Thus, it may be beneficial to continue performing IDD if success can be predicted after the IDD, or terminate IDD (i.e., not continue IDD) if failure is predicted to occur after the IDD. Accordingly, wasting of resources may be reduced (e.g., avoided or prevented).

In some embodiments, an LLR of a code block or transmit block may be considered to determine a confidence factor of that block. More particularly, the confidence factor from the LLR may be used to determine or predict the likelihood of a cyclic-reduction checksum (CRC) passing or failing. For example, as known by those skilled in the art, CRC is an error detection scheme wherein a successful CRC indicates an error-free symbol whereas an unsuccessful CRC indicates that there may be an error in the symbol. Thus, if the CRC is predicted to be successful based on the LLR confidence factor, then the IDD may continue. On the other hand, if the CRC is predicted to be unsuccessful based on the LLR confidence factor, then the IDD may be terminated (e.g., early termination). Herein the present disclosure, this prediction may be determined or computed according to various metrics, which will be described in more detail later. In some embodiments, the metric may be determined at the output of the decoder 102 based on the LLR, and the metric may be compared with a threshold to predict whether the IDD is going to succeed or fail.

In some embodiments, the bits are structured as blocks. That is, the bits may be grouped into code blocks, wherein each code block includes several bits. Several code blocks (CB) may be grouped together to form a transmit block (TB). Each code block may be encoded and decoded independently of one another. Therefore, for example, if there is an error in one code block out of the several code blocks in a transmit block, the error is independent to that code block and does not necessarily affect or cause an error in another code block. On the other hand, if there is an error in one code block, then the entire transmit block may be considered to have an error.

Thus, because the code blocks are independent of one another, if one code block is successful and another code block is unsuccessful after performing one iteration of IDD, then further iterations are not performed on the successful code block because that code block has already passed and power can be conserved by terminating the IDD for this code block. However, a further iteration of IDD may be performed on the code block that failed if it can be predicted that performing further iterations of IDD will be successful. If it predicts that further iterations will still not result in success, then IDD may be terminated. Accordingly, various techniques for performing such smart predictions will be described.

According to an embodiment of the present disclosure, a code block level early termination may be performed during operation of a first iteration of detecting and decoding, for example, by the system illustrated in FIG. 1.

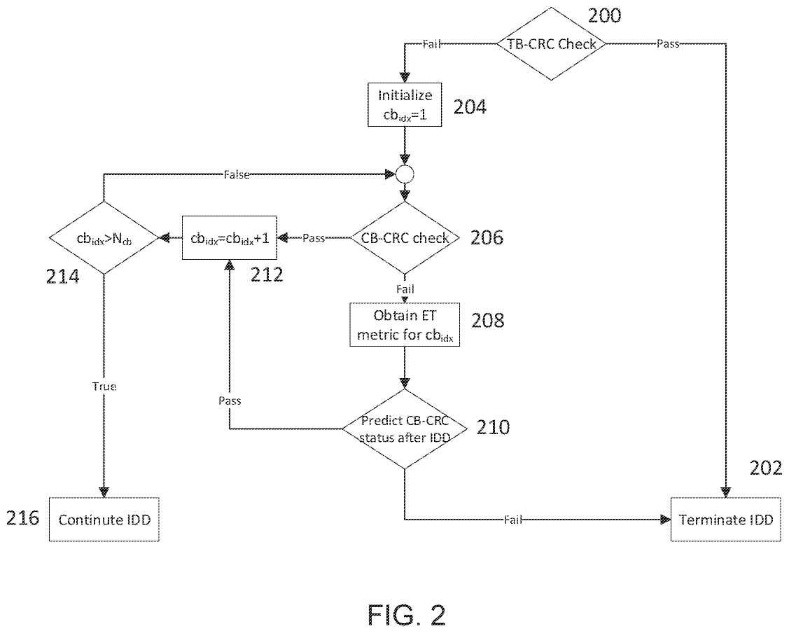

FIG. 2 is a flow chart of the code block level early termination technique, according to an embodiment of the present disclosure. At step 200, the CRC for the transmit block is determined. If the CRC for the transmit block passes, then the detecting and decoding process may be terminated at step 202 because a successful CRC indicates that the transmission was properly received and properly decoded. In other words, the detection and decoding may be terminated after the first iteration and therefore multiple iterations, such as IDD does not have to be performed.

If the CRC for the transmit block fails, then further evaluation at the code block level may be performed. Thus, at step 204, a code block index is set to 1, which indicates that the first code block of the transmit block will be examined independently from the other code blocks. At step 206, a CRC of the code block is determined. If the CRC of the code block fails, then at step 208, the entire LLRs of the failed code block are examined to obtain an early termination decision metric. Consequently, at step 210, this metric may be used to predict whether or not the CRC check of the code block will be successful if another iteration of the IDD is performed. If it is predicted that the future CRC after another IDD iteration will fail, then the IDD operation may be terminated at step 202.

If the CRC check at step 206 is successful, then at step 212, the code block index is incremented to the next index (e.g., 2). At step 214, if the code block index is less than the total number of code blocks in the transmit block, then the next code block is examined. Accordingly, step 206 is repeated where the CRC of the next code block (e.g., code block of index 2) is computed to determine whether it is successful or fails, and the remaining steps are repeated as already explained above.

Turning back to step 214, if the code block index is greater than the total number of code blocks in the transmit block, then this indicates that all code blocks have been examined, and that there are no more code blocks in this transmit block that need to be examined. Therefore, at step 216, IDD may be continued.

Accordingly, metrics for the code blocks of the transmit block that failed may be computed by using the LLRs of the code block, and this metric may be compared with some threshold value (which may be a predetermined or pre-set threshold value) to make a prediction as to whether the CRC for the code block will pass or fail in the next or further iterations of IDD. If the prediction is that the CRC is going to fail, then the IDD is terminated because it is better to terminate and conserve resources (e.g., power, memory) if a further iteration is not going to produce desirable results (i.e., passing CRC).

According to this technique, if the CRC of even one code block is predicted to fail, then the IDD for the entire transmit block will be terminated. However, if the prediction for the CRC of the first code block is predicted to be successful, then the next code block is checked, and so on if they continue to be predicted to be successful. When all of the code blocks are examined and all of them are predicted to be successful, then the IDD will continue. Otherwise, when one code block is predicted to fail, then the IDD for the entire transmit block is terminated.

For example, in a 1 codeword case where the MIMO transmission includes a transmission of only one codeword, the LLRs of all CRC failing CBs may be examined independently and then terminate the IDD even if one code block is predicted to fail, but proceed with a second global iteration if all code blocks are predicted to pass. An example pseudo-code of CB-level early termination for the 1 codeword case (e.g., 5G-NR) is shown below in Table 1 where Early_Terminate_Func represents the operation of different possible early termination schemes using different early termination decision metrics, which will be described later in more detail.

TABLE 1

```
IF tb_crc == PASS // TB level CRC check
  Terminate IDD;
ELSE
    FOR cb_idx = 1 to cb_num
      IF cb_crc(cb_idx)== PASS
        early_terminate_decision(cb_idx) = 0;
      ELSE
        early_terminate_decision(cb_idx) =
        Early_Terminate_Func( LLRs(cb_idx) );
      END IF
    END FOR
    IF any(early_terminate_decision)
      terminate IDD;
    ELSE
      continue;
    END IF
END IF
```

For a 2 codeword case where the MIMO transmission includes a transmission of two codewords, a difference between NR-MIMO (up to Rank4) and LTE-MIMO is in codeword to layer mapping where in NR, a single codeword (e.g., TB) may be mapped to all layers (up to 4 layer case) and in LTE, two codewords (e.g. two TBs) may be mapped to all the available layers. It may be assumed that parallel IDD structure is utilized for the 2 codeword case where all layers (corresponding to two codewords) are detected in parallel. Therefore, per codeword early termination is not declared but instead early termination may be declared for either both codewords or continue with the IDD operation for both. Accordingly, an early termination decision per codeword is determined first, and IDD early termination is declared only if both codewords declare early termination. Furthermore, for codeword decision, the LLR features corresponding to both codewords may be utilized. An example pseudo-code summarizing the operation of CB-level early termination for LTE is shown in Table 2.

```
TABLE 2
IF tb_crc(CW1) == PASS AND tb_crc(CW2) == PASS
  terminate IDD;
ELSE
    FOR cw_idx = 1 to 2
        FOR cb_idx = 1 to cb_num
            IF cb_crc(cb_idx,cw_idx)== PASS
              early_terminate_decision(cb_idx) = 0;
          ELSE
              early_terminate_decision(cb_idx) =
      Early_Terminate_Func( LLRs(cb_idx) );
          END IF
        END FOR
        IF any(early_terminate_decision)
          early_terminate_cw(cw_idx) = 1;
        END IF
  END FOR
    IF early_terminate_cw(1) == 1 && early_terminate_cw(2) == 1
      terminate IDD;
    ELSE
      continue;
    END IF
END IF
```

According to another embodiment of the present disclosure, a per code block early termination technique may be performed. Like the code block level early termination technique described above, the CRC for the transmit block level is computed and evaluated to determine whether the CRC passes or fails. If the CRC for the transmit block passes, then the detecting and decoding process may be terminated because a successful CRC indicates that the transmission was properly received and properly decoded. In other words, the detection and decoding may be terminated after the first iteration and therefore multiple iterations, such as IDD does not have to be performed.

If the CRC for the transmit block fails, then further evaluation at the code block level may be performed. Accordingly, metrics for the code blocks of the transmit block that failed may be computed by using the LLR to determine a prediction as to whether the CRC for the code block will pass or fail in the next or further iteration. It should be noted that the process for the per code block early termination and the code block level early termination are the same up to this point.

However, if the prediction is that the CRC is going to pass, then the IDD for that code block may continue to operate independently. Thus, the metric for the next code block may be computed and considered, and if the CRC is predicted to fail, then the IDD is terminated for the code block that was predicted to fail the CRC, and the IDD for any of the code blocks that are predicted to pass may continue to operate IDD. Thus, the metric calculation is performed at the code block and the early termination also at the code block level in this per code block early termination technique. This can be helpful during retransmissions and perform less decoding in the retransmissions.

For example, in HARQ ON mode, the target may be to pass as many code block CRCs as possible in first transmission independent of the expected outcome of the transmit block CRC check. For HARQ ON, even if the transmit block CRC fails, the code block CRC passing may be beneficial in reducing the decoding overhead in retransmissions. Thus, according to the per code block early termination technique, the LLRs of all CRC failing code blocks may be examined independently, but continue with the IDD processing of code blocks that are predicted to pass the code block CRC, and terminate IDD the processing of code blocks CRC that are predicted to fail. An example pseudo-code of per code block early termination for NR is shown in Table 3 below where Early_Terminate_Func represents the operation of different possible early termination schemes such as MI-based, mean LLR-based and SCR-based.

TABLE 3

```
IF tb_crc == PASS // TB level CRC check
  Terminate IDD;
ELSE
    FOR cb_idx = 1 to cb_num
      IF cb_crc(cb_idx)== PASS
          early_terminate_decision(cb_idx) = 1;
      ELSE
          early_terminate_decision(cb_idx) =
  Early_Terminate_Func( LLRs(cb_idx) );
      END IF
    END FOR
    IF all(early_terminate_decision)
      terminate IDD;
    ELSE
      continue IDD;
      FOR cb_idx = 1 to cb_num
        IF (early_terminate_decision(cb_idx) == 0)
          process CB #cb_idx
        END
      END FOR
    END IF
END IF
```

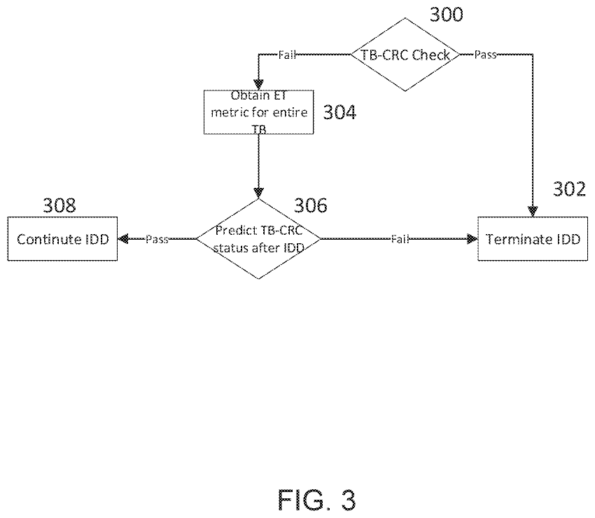

According to another embodiment of the present disclosure, a transmit block level early termination technique may be performed. FIG. 3 is a flow chart of the transmit block level early termination technique, according to an embodiment of the present disclosure. Again, like the code block level early termination technique and the per code block early termination technique described above, at step 300, the CRC for the transmit block level is computed and evaluated to determine whether the CRC passes or fails. If the CRC for the transmit block passes, then at step 302, the detecting and decoding process may be terminated because a successful CRC indicates that the transmission was properly received and properly decoded. In other words, the detection and decoding may be terminated after the first iteration and therefore multiple iterations, such as IDD does not have to be performed.

However, if the CRC for the transmit block level fails, then the LLRs for the entire transmit block are computed and a metric is computed based on these LLRs at step 304. If the CRC for the transmit block is predicted at step 306 to fail, then the IDD is terminated for the entire transmit block at step 302. On the other hand, if the CRC for the transmit block is predicted to pass at step 306, then the IDD continues at step 308 for the whole transmit block. Accordingly, this technique examines metric at the transmit block level and terminate the IDD also at the transmit level if the conditions are met for early termination. An example of a pseudo-code summarizing the operation of transmit block level early termination is shown in Table 4 below.

TABLE 4

```
IF tb_crc == PASS
  early_terminate_decision = 1;
ELSE
  early_terminate_decision = Early_Terminate( LLRs(tb_idx) );
END IF
if early_terminate_decision
  terminate IDD;
else
  continue;
end
```

Next, according to various embodiments of the present disclosure, techniques for computing the metrics that may be used by the above-described early termination techniques will be described in more detail. According to some embodiments, the metric may be computed by mutual information based early termination metric. This metric may be computed by obtaining mutual information between the transmitted bits and the extrinsic LLRs at the output of the decoder. The mutual information (MI) may be represented by:

$${MI}_{i} = I ( {x}_{i} ; {llr}_{i} ) = H ( {x}_{i} ) - H ( {x}_{i} \vert {LLR}_{i} ) = 1 - H ( {x}_{i} \vert {LLR}_{i} )$$

$${p}_{i} = P ( {x}_{i} = 0 \vert {llr}_{i} ) = \frac{{e}^{\frac{{llr}_{i}}{2}}}{{e}^{\frac{{llr}_{i}}{2}} + {e}^{- \frac{{llr}_{i}}{2}}}$$

$${MI}_{i} = 1 - ( - {p}_{i} {log}_{2} {p}_{i} - ( 1 - {p}_{i} ) {log}_{2} ( 1 - {p}_{i} ) )$$

$$MI = mean ( {MI}_{t} ) = 1 - \frac{1}{N} {\sum }_{i} ( - {p}_{i} {log}_{2} {p}_{i} - ( 1 - {p}_{i} ) {log}_{2} ( 1 - {p}_{i} ) ) ,$$

wherein
xᵢ is the i-th transmitted bit, and
llrᵢ^{DEC,OUT} (or equivalently llrᵢ) is the LLR at the output of the decoder, and the i corresponds to the bit position index. That is, the mutual information may be determined by computing an LLR metric for each bit position at the output of the decoder, and then averaging all of these the LLRs over peak positions. Once the mutual information is computed, the MI may be compared with a pre-set or predetermined threshold to predict the status of CRC check (e.g., whether the CRC is likely to pass or fail) in next global iteration. For example, if MI(cb_{idx})<Thr_{MI}, then the prediction may be that the CRC will fail and therefore the IDD may be terminated, whereas if MI(cb_{idx})≥Thr_{MI}, then the prediction may be that the CRC will pass and therefore the IDD may continue.

According to another embodiment, the metric may be computed by a mean-LLR based early termination metric. The mean-LLR based early termination metric may obtain an average of LLR magnitudes according to the equation:

$$mean\_LLR = \frac{1}{N} {\sum }_{i} \vert {llr}_{i} \vert$$

where the mean of the magnitude of all of the LLRs are computed, and then the mean is compared to a pre-set or predetermined threshold to predict the CRC check in next global iteration. Accordingly, many thousands of LLRs can be narrowed down to just one metric, namely, the mean LLR out of all of the LLRs, which is then compared with the threshold. Thus, if the mean_LLR(cb_{idx})<Thr_{meanLLR}, then it is predicted that the CRC will fail and therefore the IDD may be terminated. Otherwise, if the mean_LLR(cb_{idx})≥Thr_{meanLLR}, then it is predicted that the CRC will be successful and so the IDD may continue.

According to another embodiment, the metric may be computed by a sign change ratio (SCR) based early termination technique. According to the SCR based early termination metric, the number of times that the LLR sign at the output of the decoder changes relative to the LLR sign at the input of the decoder is computed. Thus, the ratio of the sign change for the total number of bits—may be computed according to the following equation:

$$SCR = \frac{\begin{matrix}{\sum }_{i = 1}^{N} ( sign ( {llr}_{i}^{DEC , OUT} ) \neq \\ sign ( {llr}_{i}^{DEC , IN} ) \& {llr}_{i}^{DEC , IN} \neq 0 \& {llr}_{i}^{DEC , OUT} \neq 0 )\end{matrix}}{( N - {N}_{Erasures} )}$$

$${N}_{Erasures} = {\sum }_{i = 1}^{N} ( {llr}_{i}^{DEC , IN} == 0 OR {llr}_{i}^{DEC , OUT} == 0 )$$

wherein the LLR is the LLR at the output of the decoder and i is the bit position index. It is noted that the bit positions with either the decoder input being zero LLR or decoder output zero extrinsic LLR, are excluded. The computed SCR metric may then be compared with a pre-set or predetermined threshold to predict whether or not the CRC check in next global iteration will pass or fail. If the SCR(cb_{idx})>Thr_{SCR}, then it is predicted that the CRC will fail and therefore, the IDD may be terminated. If the SCR(cb_{idx}); Thr_{SCR}, then the CRC is expected to pass and therefore the IDD may be continued. Accordingly, even though there are many LLRs, various metrics may be used to determine a prediction.

According to another embodiment, the metric may be computed by a zero LLR ratio (ZLR) based early termination technique. The ZLR based early termination metric may be based on the number of zero LLRs at both the decoder input LLRs and the decoder output extrinsic LLRs. Based on this count, a ratio of zero LLRs to the total number of bits is computed using the following equation:

$$ZLR = \frac{{N}_{Erasures}}{N} = \frac{{\sum }_{i = 1}^{N} ( {llr}_{i}^{DEC , IN} == 0 OR {llr}_{i}^{DEC , OUT} == 0 )}{N}$$

Once the ZLR is computed, the ratio may be computed and the resulting metric may be compared with a pre-set or predetermined threshold to predict whether the CRC check will pass or fail in next global iteration. If ZLR(cb_{idx})>Thr_{ZLR}, then the CRC is predicted to fail and therefore the IDD may be terminated. On the other hand, if ZLR(cb_{idx})≤Thr_{ZLR}, then the CRC is predicted to pass and therefore the IDD may continue.

As described above, various early termination strategies may be performed by utilizing various metrics to predict and determine whether IDD should be terminated. When many global iterations of IDD are performed, processing budget (e.g., based on power consumption) may become an even greater concern. For example, performing one or two global iterations may not consumer much power but performing six global iterations may have a greater impact on power. Thus, in cases where more than two global iterations are performed, further considerations are given to availability of processing budget.

Thus, in some embodiments, a first CRC failing code block after one global iteration is examined to predict the status of the CRC check after 2nd, 3rd, . . . and Nth global iteration. In other words, a prediction is independently made as to the whether the CRC will pass or fail after the 2^{nd}, 3^{rd}, . . . and Nth global iteration. For example, using the SCR metric, if SCR_{cb_idx}>scr_thr_{gi_idx}, the corresponding code block (CB_{cb_idx}) is predicted as CRC failing after GI=gi_idx, wherein cb_idx represents the code block index, SCR_{cb_idx} represents the SCR corresponding to CB_{cb_idx} and gi_idx represents the GI index.

After a prediction is determined for each of the 2^{nd} through Nth global iteration, the number of CRC failing code blocks after gi_idx number of global iterations is estimated as cb_fail_cnt_{gi_idx}=Σ_{cb_idx}I(SCR_{cb_idx}>scr_thr_{gi_idx}), wherein I(.) denotes the indicator function with I(TRUE)=1 and I(FALSE)=0.

Finally, early termination may be declared even if only one of the following conditions is violated:
cb_fail_cnt₁>G
cb_fail_cnt₂>G−cb_fail_cnt₁
cb_fail_cnt₃>G−cb_fail_cnt₁−cb_fail_cnt₂
cb_fail_cnt₄>G−cb_fail_cnt₁−cb_fail_cnt₂−cb_fail_cnt₃
cb_fail_cnt₅>G−cb_fail_cnt₁−cb_fail_cnt₂−cb_fail_cnt₃−cb_fail_cnt₄,

where G denotes the remaining code block processing budget after the first global iteration, and cb_fail_cntᵢ denotes the consumed processing budget from the previous global iteration. Thus, if the predicted consumed processing budget is greater than the remaining code block processing budget, then early termination is declared. For subsequent global iterations, the predicted consumed processing budget is compared with the remaining code block processing budget reduced by the predicted consumed processing budget from the previous global iteration, and so on. Thus, a prediction may be determined for each scenario independently and if the prediction determines that early termination should be declared, then the IDD is terminated.

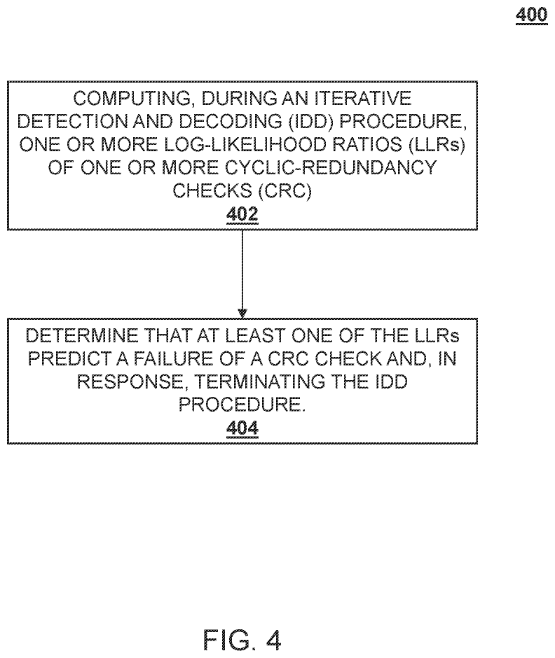

FIG. 4 is a flow chart of a method for determining early termination of IDD, according to various embodiments of the present disclosure. Thus, according to the techniques described in the embodiments, IDD may be terminated when it is determined that further performance of IDD is not likely to improve the output of the decoder. According to step 402, during an IDD procedure, one or more LLRs of one or more CRCs may be computed. Then at step 404, a determination may be made as to whether at least one of the computed LLRs predict a failure of a CRC check. In other words, the computed LLR may be used to predict whether the next or subsequent CRC check will pass or fail. If it is predicted that the CRC check will likely fail, then the IDD procedure may be terminated because further processing of the IDD procedure will consume and waste more resources (e.g., consume more power and more time), likely without getting much benefit out of it.

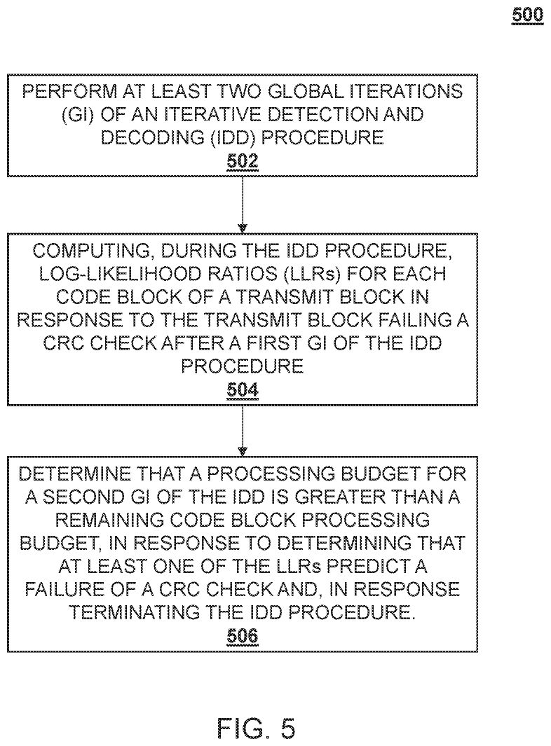

FIG. 5 is a flow chart of a method for determining early termination of IDD when two or more global iterations of IDD are performed, according to various embodiments of the present disclosure. Accordingly, at step 502, at least two global iterations of IDD are performed. Then at step 504, the LLRs for each code block of a transmit block may be computed in response to the transmit block failing a CRC check after a first global iteration of the IDD procedure. In other words, if the CRC check of a transmit block failed in the first global iteration, then the LLRs for each code block of that transmit block may be computed. Next, at step 506, a determination may be made that that processing budget for a second global iteration of the IDD is greater than a remaining code block processing budget, in response to determining that at least one of the LLRs predict a failure of a CRC check, and in response, terminating the IDD procedure. Accordingly, the IDD may be terminated in cases where there are two or more global iterations if sufficient processing budget is no longer available.

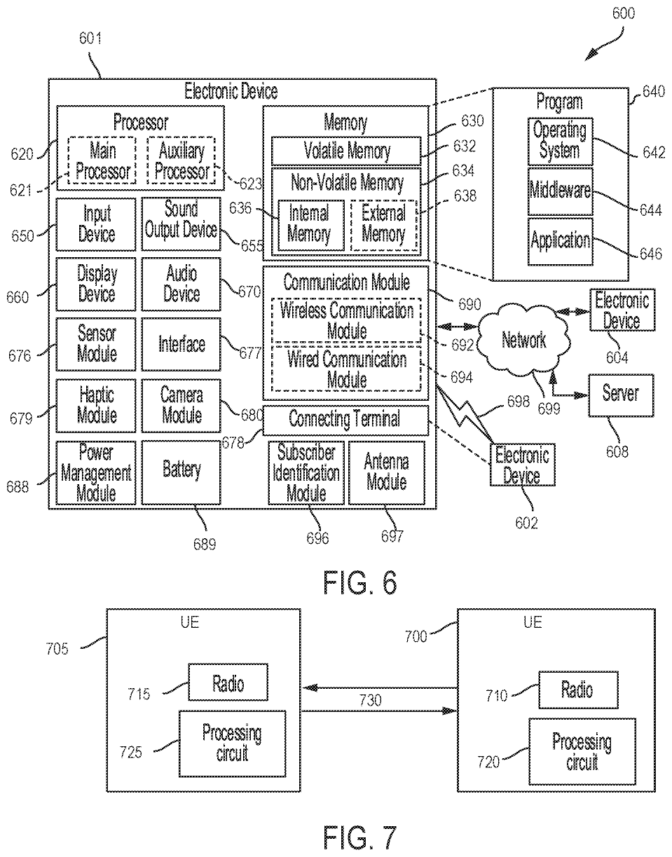

FIG. 6 is a block diagram of an electronic device in a network environment 600, according to an embodiment.

Referring to FIG. 6, an electronic device 601 in a network environment 600 may communicate with an electronic device 602 via a first network 698 (e.g., a short-range wireless communication network), or an electronic device 604 or a server 608 via a second network 699 (e.g., a long-range wireless communication network). The electronic device 601 may communicate with the electronic device 604 via the server 608. The electronic device 601 may include a processor 620, a memory 630, an input device 640, a sound output device 655, a display device 660, an audio module 670, a sensor module 676, an interface 677, a haptic module 679, a camera module 680, a power management module 688, a battery 689, a communication module 690, a subscriber identification module (SIM) card 696, or an antenna module 694. In one embodiment, at least one (e.g., the display device 660 or the camera module 680) of the components may be omitted from the electronic device 601, or one or more other components may be added to the electronic device 601. Some of the components may be implemented as a single integrated circuit (IC). For example, the sensor module 676 (e.g., a fingerprint sensor, an iris sensor, or an illuminance sensor) may be embedded in the display device 660 (e.g., a display).

The processor 620 may execute software (e.g., a program 640) to control at least one other component (e.g., a hardware or a software component) of the electronic device 601 coupled with the processor 620 and may perform various data processing or computations.

As at least part of the data processing or computations, the processor 620 may load a command or data received from another component (e.g., the sensor module 646 or the communication module 690) in volatile memory 632, process the command or the data stored in the volatile memory 632, and store resulting data in non-volatile memory 634. The processor 620 may include a main processor 621 (e.g., a central processing unit (CPU) or an application processor (AP)), and an auxiliary processor 623 (e.g., a graphics processing unit (GPU), an image signal processor (ISP), a sensor hub processor, or a communication processor (CP)) that is operable independently from, or in conjunction with, the main processor 621. Additionally or alternatively, the auxiliary processor 623 may be adapted to consume less power than the main processor 621, or execute a particular function. The auxiliary processor 623 may be implemented as being separate from, or a part of, the main processor 621.

The auxiliary processor 623 may control at least some of the functions or states related to at least one component (e.g., the display device 660, the sensor module 676, or the communication module 690) among the components of the electronic device 601, instead of the main processor 621 while the main processor 621 is in an inactive (e.g., sleep) state, or together with the main processor 621 while the main processor 621 is in an active state (e.g., executing an application). The auxiliary processor 623 (e.g., an image signal processor or a communication processor) may be implemented as part of another component (e.g., the camera module 680 or the communication module 690) functionally related to the auxiliary processor 623.

The memory 630 may store various data used by at least one component (e.g., the processor 620 or the sensor module 676) of the electronic device 601. The various data may include, for example, software (e.g., the program 640) and input data or output data for a command related thereto. The memory 630 may include the volatile memory 632 or the non-volatile memory 634.

The program 640 may be stored in the memory 630 as software, and may include, for example, an operating system (OS) 642, middleware 644, or an application 646.

The input device 650 may receive a command or data to be used by another component (e.g., the processor 620) of the electronic device 601, from the outside (e.g., a user) of the electronic device 601. The input device 650 may include, for example, a microphone, a mouse, or a keyboard.

The sound output device 655 may output sound signals to the outside of the electronic device 601. The sound output device 655 may include, for example, a speaker or a receiver. The speaker may be used for general purposes, such as playing multimedia or recording, and the receiver may be used for receiving an incoming call. The receiver may be implemented as being separate from, or a part of, the speaker.

The display device 660 may visually provide information to the outside (e.g., a user) of the electronic device 601. The display device 660 may include, for example, a display, a hologram device, or a projector and control circuitry to control a corresponding one of the display, hologram device, and projector. The display device 660 may include touch circuitry adapted to detect a touch, or sensor circuitry (e.g., a pressure sensor) adapted to measure the intensity of force incurred by the touch.

The audio module 670 may convert a sound into an electrical signal and vice versa. The audio module 670 may obtain the sound via the input device 650 or output the sound via the sound output device 655 or a headphone of an external electronic device 602 directly (e.g., wired) or wirelessly coupled with the electronic device 601.

The sensor module 676 may detect an operational state (e.g., power or temperature) of the electronic device 601 or an environmental state (e.g., a state of a user) external to the electronic device 601, and then generate an electrical signal or data value corresponding to the detected state. The sensor module 676 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 677 may support one or more specified protocols to be used for the electronic device 601 to be coupled with the external electronic device 602 directly (e.g., wired) or wirelessly. The interface 677 may include, for example, a high-definition multimedia interface (HDMI), a universal serial bus (USB) interface, a secure digital (SD) card interface, or an audio interface.

A connecting terminal 678 may include a connector via which the electronic device 601 may be physically connected with the external electronic device 602. The connecting terminal 678 may include, for example, an HDMI connector, a USB connector, an SD card connector, or an audio connector (e.g., a headphone connector).

The haptic module 679 may convert an electrical signal into a mechanical stimulus (e.g., a vibration or a movement) or an electrical stimulus which may be recognized by a user via tactile sensation or kinesthetic sensation. The haptic module 679 may include, for example, a motor, a piezoelectric element, or an electrical stimulator.

The camera module 680 may capture a still image or moving images. The camera module 680 may include one or more lenses, image sensors, image signal processors, or flashes. The power management module 688 may manage power supplied to the electronic device 601. The power management module 688 may be implemented as at least part of, for example, a power management integrated circuit (PMIC).

The battery 689 may supply power to at least one component of the electronic device 601. The battery 689 may include, for example, a primary cell which is not rechargeable, a secondary cell which is rechargeable, or a fuel cell.

The communication module 690 may support establishing a direct (e.g., wired) communication channel or a wireless communication channel between the electronic device 601 and the external electronic device (e.g., the electronic device 602, the electronic device 604, or the server 608) and performing communication via the established communication channel. The communication module 690 may include one or more communication processors that are operable independently from the processor 620 (e.g., the AP) and supports a direct (e.g., wired) communication or a wireless communication. The communication module 690 may include a wireless communication module 692 (e.g., a cellular communication module, a short-range wireless communication module, or a global navigation satellite system (GNSS) communication module) or a wired communication module 694 (e.g., a local area network (LAN) communication module or a power line communication (PLC) module). A corresponding one of these communication modules may communicate with the external electronic device via the first network 698 (e.g., a short-range communication network, such as Bluetooth™, wireless-fidelity (Wi-Fi) direct, or a standard of the Infrared Data Association (IrDA)) or the second network 699 (e.g., a long-range communication network, such as a cellular network, the Internet, or a computer network (e.g., LAN or wide area network (WAN)). These various types of communication modules may be implemented as a single component (e.g., a single IC), or may be implemented as multiple components (e.g., multiple ICs) that are separate from each other. The wireless communication module 692 may identify and authenticate the electronic device 601 in a communication network, such as the first network 698 or the second network 699, using subscriber information (e.g., international mobile subscriber identity (IMSI)) stored in the subscriber identification module 696.

The antenna module 697 may transmit or receive a signal or power to or from the outside (e.g., the external electronic device) of the electronic device 601. The antenna module 697 may include one or more antennas, and, therefrom, at least one antenna appropriate for a communication scheme used in the communication network, such as the first network 698 or the second network 699, may be selected, for example, by the communication module 690 (e.g., the wireless communication module 692). The signal or the power may then be transmitted or received between the communication module 690 and the external electronic device via the selected at least one antenna.

Commands or data may be transmitted or received between the electronic device 601 and the external electronic device 604 via the server 608 coupled with the second network 699. Each of the electronic devices 602 and 604 may be a device of a same type as, or a different type, from the electronic device 601. All or some of operations to be executed at the electronic device 601 may be executed at one or more of the external electronic devices 602, 604, or 608. For example, if the electronic device 601 should perform a function or a service automatically, or in response to a request from a user or another device, the electronic device 601, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 601. The electronic device 601 may provide the outcome, with or without further processing of the outcome, as at least part of a reply to the request. To that end, a cloud computing, distributed computing, or client-server computing technology may be used, for example.

FIG. 7 shows a system including a first electronic device, such as, for example a first user equipment (UE) 705 and a second electronic device such as, for example, a second UE 700, which may act as a receiver and/or a transmitter in communication with each other. The first and second UEs 705, 700 may include a radio 715, 710 and a processing circuit (or a means for processing) 725, 720 including the detector and the decoder, which may perform various methods such as the IDD procedures disclosed herein.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A method comprising:
computing, during an iterative detection and decoding (IDD) procedure, one or more log-likelihood ratios (LLRs) of one or more cyclic-redundancy checks (CRC); and
determining that at least one of the LLRs predict a failure of a CRC check and, in response, terminating the IDD procedure.

2. The method of claim 1, wherein the one or more LLRs are computed for each code block of a transmit block in response to the transmit block failing a CRC check after a global iteration of the IDD procedure.

3. The method of claim 2, wherein the terminating the IDD procedure is performed for all code blocks of the transmit block, the code blocks comprising at least one code block where the LLR predicts a passing CRC check.

4. The method of claim 2,
wherein the terminating the IDD procedure is performed for one or more code blocks where the LLRs predicted a failure of the CRC check, and
wherein the IDD procedure continues for at least one code block where the LLR predicts a passing CRC check.

5. The method of claim 1, wherein the one or more LLRs are computed for a transmit block in response to the transmit block failing a CRC check after a global iteration of the IDD procedure.

6. The method of claim 1,
wherein the LLR prediction of failure of the CRC check is based on computing mutual information between transmitted bits and the LLR at an output of a decoder, and
wherein the mutual information is less than a threshold value.

7. The method of claim 1,
wherein the LLR prediction of failure of the CRC check is based on computing an average value of magnitudes of all of the LLRs, and
wherein the average value of the magnitudes is less than a threshold value.

8. The method of claim 1,
wherein the LLR prediction of failure of the CRC check is based on computing a sign change ratio (SCR) between the LLR of an input of a decoder and the LLR of an output of the decoder, and
wherein the SCR is less than a threshold value.

9. The method of claim 1,
wherein the LLR prediction of failure of the CRC check is based on computing a number of zero LLRs at an input of a decoder and at an output of a decoder, and
wherein a number of zero LLRs is less than a threshold value.

10. The method of claim 1, wherein the IDD is performed for reducing power consumption in a new radio (NR) or a long-term evolution (LTE) communications system.

11. A receiver comprising:
a processing circuit comprising a detector and a decoder coupled with the detector, wherein the processing circuit is configured to:
compute, during an iterative detection and decoding (IDD) procedure, one or more log-likelihood ratios (LLRs) of one or more cyclic-redundancy checks (CRC); and
determine that at least one of the LLRs predict a failure of a CRC check and, in response, terminating the IDD procedure.

12. The receiver of claim 11, wherein the one or more LLRs are computed for each code block of a transmit block in response to the transmit block failing a CRC check after a global iteration of the IDD procedure.

13. The receiver of claim 12, wherein the terminating the IDD procedure is performed for all code blocks of the transmit block, the code blocks comprising at least one code block where the LLR predicts a passing CRC check.

14. The receiver of claim 12,
wherein the terminating the IDD procedure is performed for one or more code blocks where the LLRs predicted a failure of the CRC check, and
wherein the IDD procedure continues for at least one code block where the LLR predicts a passing CRC check.

15. The receiver of claim 11, wherein the one or more LLRs are computed for a transmit block in response to the transmit block failing a CRC check after a global iteration of the IDD procedure.

16. The receiver of claim 11,
wherein the LLR prediction of failure of the CRC check is based on computing mutual information between transmitted bits and the LLR at an output of a decoder, and
wherein the mutual information is less than a threshold value.

17. The receiver of claim 11,
wherein the LLR prediction of failure of the CRC check is based on computing an average value of magnitudes of all of the LLRs, and
wherein the average value of the magnitudes is less than a threshold value.

18. The receiver of claim 11,
wherein the LLR prediction of failure of the CRC check is based on computing a sign change ratio (SCR) between the LLR of an input of a decoder and the LLR of an output of the decoder, and
wherein the SCR is less than a threshold value.

19. The receiver of claim 11,
wherein the LLR prediction of failure of the CRC check is based on computing a number of zero LLRs at an input of a decoder and at an output of a decoder, and
wherein a number of zero LLRs is less than a threshold value.

20. The receiver of claim 11, wherein the IDD is performed for reducing power consumption in a new radio (NR) or a long-term evolution (LTE) communications system.

21. A method comprising:
performing at least two global iterations (GI) of an iterative detection and decoding (IDD) procedure;
computing, during the IDD procedure, log-likelihood ratios (LLRs) for each code block of a transmit block in response to the transmit block failing a CRC check after a first GI of the IDD procedure; and
determining that a processing budget for a second GI of the IDD is greater than a remaining code block processing budget, in response to determining that at least one of the LLRs predict a failure of a CRC check and, in response terminating the IDD procedure.
